(19) United States
(12) Patent Application Publication
(10) Pub. No.: US 2026/0017417 A1
(43) Pub. Date: Jan. 15, 2026

(54) INFORMATION PROCESSING METHOD, COMPUTER-READABLE MEDIUM, AND INFORMATION PROCESSING APPARATUS

(71) Applicant: Tokyo Electron Limited, Tokyo (JP)

(72) Inventors: Ryoji ANZAKI, Tokyo (JP); Yuma YAZAKI, Sapporo City (JP); Toshihiro KITAO, Sapporo City (JP)

(73) Assignee: Tokyo Electron Limited, Tokyo (JP)

(21) Appl. No.: 19/335,081

(22) Filed: Sep. 22, 2025

Related U.S. Application Data
(63) Continuation of application No. PCT/JP2024/012644, filed on Mar. 28, 2024.

(30) Foreign Application Priority Data
Mar. 30, 2023 (JP) 2023-055561

(51) Int. Cl. G06F 30/10; G06F 17/11; G06F 30/20

(52) U.S. Cl. CPC G06F 30/10; G06F 17/11; G06F 30/20

(57) ABSTRACT

An information processing method, computer-readable medium, and an information processing apparatus optimizes a physical system. The information processing apparatus stores, in a memory circuit, a system model obtained by coupling component models obtained by modeling physical components included in a physical system and modeling the physical system, receives a setting of an objective function for performing an arithmetic operation based on an output value of the system model, determines an allowed region for an input value, in which an output value of the objective function satisfies a predetermined condition, determines an allowed region for an input value of the component model in which an output value of the component model falls within the allowed region, for the component model outputting the input value, and determines an allowed region for an input value of the system model by determining the allowed region for component models constituting the system model.

### CROSS-REFERENCE TO RELATED APPLICATIONS

This application is a bypass continuation application of international application No. PCT/JP2024/012644 having an international filing date of Mar. 28, 2024, and which claims priority to Japanese Patent Application No. 2023-055561, filed on Mar. 30, 2023. The entire contents of both of these application are hereby incorporated by reference.

### TECHNICAL FIELD

The present disclosure relates to an information processing method, a computer-readable medium, and an information processing apparatus.

### BACKGROUND

PTL 1 proposes a model constructing method including receiving a hierarchical tree structure defining nodes associated with hardware of a physical system, collecting data including time stamps and observation data associated with hardware components, deriving node states of the nodes based on the collected data, constructing a finite state machine (FSM) model defining a sequence of states associated with the nodes based on the time stamps, and creating a model of the physical system by using the FSM model as a part of an overall finite state machine of a physical system.

### CITATION LIST

### Patent Documents

PTL 1: JP2021-536626A

### SUMMARY

The present disclosure provides an information processing method, a computer program, and an information processing apparatus for optimizing a physical system.

In the information processing method according to an aspect, the information processing apparatus stores, in a memory circuit, a system model obtained by coupling component models obtained by respectively modeling physical components included in a physical system and modeling the physical system, receives a setting of an objective function for performing an arithmetic operation based on an output value of the system model, determines an allowed region for an input value of the system model, in which an output value of the objective function satisfies a predetermined condition, determines an allowed region for an input value of the component model in which an output value of the component model falls within the allowed region, for the component model outputting the input value, and determines an allowed region for the input value of the system model by determining the allowed region for component models constituting the system model.

According to the present disclosure, it can be expected to optimize a physical system.

### BRIEF DESCRIPTION OF DRAWINGS

FIG. 1 is a schematic diagram illustrating an example of an overview of an information processing system according to the present embodiment;

FIG. 2 is a block diagram illustrating an example of a configuration of an information processing apparatus provided in the information processing system according to the present embodiment;

FIG. 3 is a flowchart illustrating an example of a procedure of optimization processing performed by the information processing apparatus according to the present embodiment;

FIG. 4 is a schematic diagram illustrating an example of a method for determining an allowed region;

FIG. 5 is a schematic diagram illustrating a display example of an optimization result;

FIG. 6 is a schematic diagram illustrating an example of a configuration of a system model according to a modification;

FIG. 7 is a schematic diagram illustrating an overview of an information processing system according to a second embodiment; and

FIG. 8 is a flowchart illustrating an example of a procedure of optimization processing performed by an information processing apparatus according to the second embodiment.

### DETAILED DESCRIPTION

Hereinafter, a specific example of an information processing system according to the embodiment of the present disclosure will be described with reference to the drawings. The present disclosure is not limited to these examples, and is defined by the claims, and is intended to include all modifications within the meaning and scope equivalent to the claims.

### First Embodiment

### System Overview

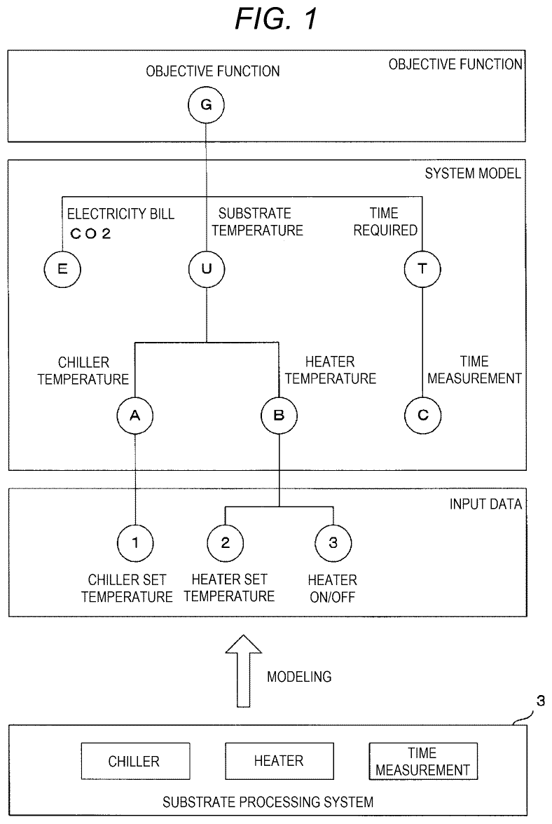

FIG. 1 is a schematic diagram illustrating an example of an overview of an information processing system according to the present embodiment. The information processing system according to the present embodiment is a system that simulates a physical system present in a real space (physical space) in a virtual space (digital space or cyberspace), and performs management and control of the physical system. This is a technique that can be referred to as a so-called digital twin. In the present embodiment, the information processing system controls, as an example of a physical system, a digital twin in which a substrate processing system 3 for performing substrate processing such as manufacturing of a semiconductor wafer is simulated in a virtual space.

In the digital twin technique, a system model obtained by modeling the substrate processing system 3 is created based on various pieces of data collected by the substrate processing system 3. In the present embodiment, the system model includes component models obtained by individually modeling each of a plurality of components such as chillers, heaters, and time measurements constituting the substrate processing system 3. In FIG. 1, the component model is indicated by a circular symbol, a component model A corresponds to a chiller of the substrate processing system 3, a component model B corresponds to a heater, and a component model C corresponds to time measurement.

Further, in the present embodiment, the system model is configured such that a plurality of component models are coupled in a hierarchical manner. The illustrated system model includes a hierarchy including the component models A, B, and C described above, and a hierarchy including component models E, U, and T as a hierarchy immediately above this hierarchy. Hereinafter, the hierarchy including the component models E, U, and T will be referred to as a first hierarchy, and the hierarchy including the component models A, B, and C will be referred to as a second hierarchy. The component models E, U, and T in the first hierarchy perform various predictions regarding the processing by the substrate processing system 3 based on data obtained from the component models A, B, and C in the second hierarchy. The component models A, B, and C in the second hierarchy predict processing results of functions such as chillers, heaters, and time measurements of the substrate processing system 3, based on input data to the substrate processing system 3.

These component models are created in advance by extracting input data to the components and output data of the components from the data collected for the substrate processing system 3, and adjusting parameters and the like of the model so as to reproduce a correspondence relationship between the input and output based on the extracted data. The component model may be represented by, for example, an arithmetic expression based on the physical characteristics of the components, or may be, for example, a machine learning model such as a neural network, or may be a model having other configurations.

For example, the component model Ain the second hierarchy is a model that acquires chiller set temperature as input data 1 and predicts chiller temperature of the substrate processing system 3. The component model B is a model that acquires heater set temperature as input data 2 and acquires ON/OFF settings of the heater as input data 3 to predict heater temperature of the substrate processing system 3. The component model C is a model that measures processing time of the substrate processing system 3 in the virtual space. In FIG. 1, the input data to the component model C is not illustrated. However, for example, data such as ON/OFF of a power source of the substrate processing system 3, starting/stopping of the substrate processing, and the like may be input to the component model C.

Further, for example, a component model E in the first hierarchy is a model that predicts an environmental load such as electricity bills or the amount of carbon dioxide emissions that accompany the operation of the substrate processing system. In FIG. 1, component models in the second hierarchy, to which the component model E is coupled, are omitted. A component model U is a model that predicts, based on the chiller temperature output from the component model A in the second hierarchy and the heater temperature output from the component model B, temperature of the substrate processed by the substrate processing system 3. A component model T is a model that estimates time required for substrate processing performed by the substrate processing system 3 based on the time measurement results output from the component model C.

That is, the illustrated system model includes three component models E, U, and T in the first hierarchy, and includes three component models A, B, and C in the second hierarchy. The component models A and B in the second hierarchy are coupled to the component model U in the first hierarchy, and the component model C in the second hierarchy is coupled to the component model T in the first hierarchy. The illustrated system model is an example, and is not limited thereto. The illustrated system model is simplified, and an actual system model may be implemented by coupling more component models divided into more layers. That is, the system model handled by the information processing system may have a hierarchical structure of three or more hierarchies. Further, the system model may be a model in which the plurality of component models do not form a hierarchical structure, that is, form one hierarchy alone.

For example, the information processing system acquires various pieces of data measured by sensors or the like from the substrate processing system 3 for performing substrate processing, inputs the acquired data into a system model, and acquires data such as various predicted values output by the system model in response to the input of the data. Based on the acquired data, the information processing system can monitor the operation status of the substrate processing system 3, predict characteristics of the substrate processed by the substrate processing system 3, or control the substrate processing system 3 using the acquired data as feedback.

Further, the information processing system according to the present embodiment can perform processing of determining conditions for input data for optimally operating the substrate processing system 3, i.e., optimization processing, using the system model of the substrate processing system 3 generated in advance, based on objectives and constraints set by a user. In this case, the user sets an objective function G obtained by expressing the objective of the optimization for the substrate processing system 3 as a function, and constraints with respect to each component model or a combination thereof.

The objective function G is a function coupled to one or more component models in the highest-level layer (first hierarchy) of the system model. The objective function G is a function that receives, as an input, one or more pieces of data output from the coupled component model, and outputs a result obtained by performing a predetermined arithmetic operation on the input data. The predetermined arithmetic operation performed according to the function and the condition for an output value of the function are set by the user. The illustrated objective function G may be set as, for example, the formula (1) below, where e is output data of the component model E, u is output data of the component model U, and t is output data of the component model T. In the formula (1), w1, w2, and w3 are weights, and Z is any numerical value.

Objective function G:w1×e+w2×u+w3×t<Z (1)

When the formula (1) is set, for example, for the substrate processing system 3 illustrated in FIG. 1, the user can set the objective of optimization to reduce the electricity bills as low as possible, to reduce the difference from a target value of the substrate temperature as small as possible, and to shorten the required time as much as possible. Further, the user can set which of these three optimizations is focused on for optimization by appropriately setting the weights w1, w2, and w3.

A method of setting the objective function is not limited to the method using the above-described formula (1), and various methods may be adopted. Further, the objective function may be automatically set by, for example, an apparatus such as an information processing apparatus, instead of being manually set by a user or the like. For example, the information processing apparatus or the like may determine the objective function based on one or more conditions or the like appropriately set for the substrate processing system 3. Further, for example, the information processing apparatus or the like may determine the objective function by machine learning using various pieces of data obtained from the substrate processing system 3. Further, for example, the objective function set in another information processing system of a similar or same type that is already operating may be acquired and used as the objective function of the present information processing system.

The constraints for each component model set by the user may be set as shown in the formula (2) below, for example, as a range of values that may be taken by the output data of the component model. In the formula (2), e1 and e2 are threshold values of the output data e of the component model E, u1 and u2 are threshold values of the output data u of the component model U, and t1 and t2 are threshold values of the output data t of the component model T.

e1<e<e2

u1<u<u2

t1<t<t2 (2)

A method of setting the constraints is not limited to the method using the above-described formula (2), and various methods may be adopted. Further, the constraints may be set in advance by, for example, a designer or an administrator of the substrate processing system 3, or a creator of the system model, the component model, or the like, instead of being set by the user. The user may modify or add constraints or the like to these constraints set in advance by the designer or the like.

The above-described constraints are an example of conditions individually set for the component models. The constraints may be set for a combination of a plurality of component models. For example, in a combination of the two component models including the chiller and the heater of the system model illustrated in FIG. 1, in order to prevent overheating, it may be conceivable to set constraints such that the heater cannot be turned on unless the chiller is operating. Of course, constraints for other combinations of components, including combinations encompassing more than two components, can be set without limitation upon the present disclosure.

As illustrated in FIG. 1, the system model to which the objective function G created by the user is coupled is a so-called tree-structure model in which the objective function G is a root node, one or more component models in the first hierarchy are coupled to the root node, one or more component models in the second hierarchy are coupled to each component model in the first hierarchy, and one or more pieces of input data for each component model in the second hierarchy is used as a leaf node. The system model to which the objective function and the input data are not coupled is a model that includes a plurality of tree structures whose root nodes are component models in the first hierarchy.

In the present embodiment, the objective function and the system model have a tree structure. However, the present disclosure is not limited thereto. The objective function and the system model may include a structure different from the tree structure, for example, a structure in which one component model in the second hierarchy is coupled to a plurality of component models in the first hierarchy.

The information processing system according to the present embodiment determines the range of values (allowed regions) that can be taken by each piece of input data to the objective function, based on the objective function and constraints set by the user. The information processing system determines, based on the allowed region for each piece of input data of the objective function, the range of values (allowed region) that each piece of input data to each component model may be taken for one or more component models located at one layer below. In this way, the information processing system can ultimately determine the allowed region for input data to the lowest-level component model by recursively repeating the determination of the allowed region for input data to the component model at one layer below in an order from the highest-level objective function. That is, in the example illustrated in FIG. 1, the allowed regions can be respectively determined for the input data 1, 2, and 3 as a result of the optimization processing using the objective function G. When each piece of input data to the substrate processing system 3 is set to be within the determined allowed region, the substrate processing system 3 can be caused to perform processing that satisfies the objective function and the constraints.

### <Apparatus Configuration>

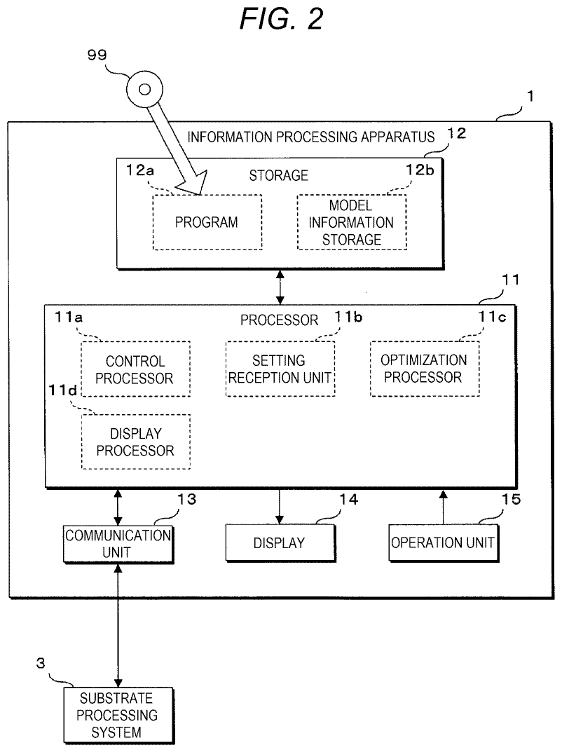

FIG. 2 is a block diagram illustrating an example of a configuration of an information processing apparatus 1 provided in the information processing system according to the present embodiment. The information processing apparatus 1 according to the present embodiment is connected to the substrate processing system 3 via a communication cable or the like, and monitors and controls the operation of the substrate processing system 3. Further, the information processing system according to the present embodiment performs the above-described monitoring, control, and the like using the system model (the digital twin of the substrate processing system 3) obtained by modeling the substrate processing system 3, and also performs processing for optimizing the operation of the substrate processing system 3 using the system model. The information processing apparatus 1 according to the present embodiment can be implemented by installing a computer program according to the present embodiment in a general-purpose information processing apparatus such as a personal computer and a server computer. The information processing apparatus 1 according to the present embodiment includes circuitry such as a processor 11 (also known as a controller or controller circuitry), a storage 12 (also known as memory or memory circuitry), a communication unit 13 (such as an input/output interface circuit or I/O interface circuitry), a display 14, an operator 15 (such as a keyboard, mouse, or other input circuitry), and the like. In the present embodiment, an example will be described in which a process is performed by one information processing apparatus 1. Meanwhile, the process of the information processing apparatus 1 may be distributed and performed by a plurality of apparatuses.

The processor 11 is configured by circuitry such as an arithmetic processing apparatus including, for example, a central processing unit (CPU), a micro-processing unit (MPU), a graphics processing unit (GPU), or a quantum processor, a read only memory (ROM), a random access memory (RAM), and the like. The processor 11 reads and executes a program 12a stored in a non-transitory computer-readable medium, such as the storage 12, to perform various types of processing, such as processing of monitoring and controlling the operation of the substrate processing system 3, and optimization processing using a system model.

The storage 12 is configured by using, for example, a large-capacity storage apparatus such as a hard disk, or other computer-readable media. The storage 12 stores various types of programs to be executed by the processor 11 and various types of data necessary for the process of the processor 11. In the present embodiment, the storage 12 stores the program 12a to be executed by the processor 11. Further, the storage 12 includes a model information storage 12b that stores information on the system model of the substrate processing system 3.

In the present embodiment, the program (computer program, program product) 12a is provided in a form recorded on a recording medium 99 such as non-transitory computer-readable media including a memory card or an optical disc. The information processing apparatus 1 reads the program 12a from the recording medium 99, and stores the program 12a in the storage 12. However, for example, the program 12a may be written into the storage 12 during a manufacturing stage of the information processing apparatus 1. For example, as the program 12a, the information processing apparatus 1 may acquire those which are distributed by a remote server device or the like through communication. For example, the program 12a may be written into the storage 12 of the information processing apparatus 1 after a writing apparatus reads data recorded in the recording medium 99. The program 12a may be provided in the form of distribution through a network, or may be provided in the form recorded in the recording medium 99.

The model information storage 12b of the storage 12 stores information on the system model of the substrate processing system 3 that has been created in advance. The information on the system model may include, for example, information on a plurality of component models included in the system model, and information on which component model each component model is coupled to. Further, the information on the component model may include, for example, information indicating the configuration of the model, and information such as internal parameters of the model determined by machine learning or the like. The information processing apparatus 1 configures a system model by reading information stored in advance in the model information storage 12b, and can be used for processing such as control and optimization of the substrate processing system 3.

The system model and the component model may be generated, for example, by performing machine learning processing using various pieces of data obtained from the substrate processing system 3. The generation of these models may be performed by the information processing apparatus 1, or the information processing apparatus 1 may acquire information on the model generated by an apparatus different from the information processing apparatus 1 and store the information in the model information storage 12b. In any case, in the information processing system according to the present embodiment, the system model of the substrate processing system 3 as illustrated in FIG. 1 is generated in advance by an appropriate method. The information on the system model is stored in advance in the model information storage 12b for use during the control or optimization of the substrate processing system 3 by the information processing apparatus 1.

The communication unit 13 is connected to the substrate processing system 3 via a cable such as a communication line or a signal line, and transmits and receives data to and from the substrate processing system 3 via the cable. In the present embodiment, the communication unit 13 transmits the control input data supplied from the processor 11 to the substrate processing system 3. Further, the communication unit 13 receives data transmitted from the substrate processing system 3, and supplies the received data to the processor 11.

The display 14 is configured by using a liquid crystal display or the like, and displays various images, characters, and the like based on the process of the processor 11. In the present embodiment, for example, the display 14 displays various types of information such as the operation statuses of the substrate processing system 3, and displays information on the results of the optimization processing. The operator 15 receives a user operation and notifies the processor 11 of the received operation. For example, the operator 15 receives the user operation by an input device such as a mechanical button or a touch panel provided on a surface of the display 14. For example, the operator 15 may be an input device such as a mouse and a keyboard, and these input devices may be configured to be detachable from the information processing apparatus 1.

The storage 12 may be an external storage device connected to the information processing apparatus 1. The information processing apparatus 1 may be a multi-computer including a plurality of computers, or may be a virtual machine virtually constructed by software. In addition, the information processing apparatus 1 is not limited to the configuration described above, and does not need to include the display 14, the operator 15, and the like, for example.

In the information processing apparatus 1 according to the present embodiment, the processor 11 reads and executes the program 12a stored in the storage 12 to implement a control processor 11a, a setting reception unit 11b, an optimization processor 11c, a display processor 11d, and the like as software functional units in the processor 11.

The control processor 11a controls the operation of the substrate processing system 3 according to, for example, a predetermined procedure of substrate processing (a semiconductor manufacturing procedure or recipe). The control processor 11a also performs processing of monitoring the operation of the substrate processing system 3 based on data obtained from the substrate processing system 3 as the substrate processing is performed. In the present embodiment, the control processor 11a predicts the quality or accuracy of the processing being performed by the substrate processing system 3 and adjusts the control of the substrate processing system 3 by feeding back prediction results, using the system model stored in the model information storage 12b.

In the information processing system according to the present embodiment, the information processing apparatus 1 performs both the control of the substrate processing system 3 and the optimization using the system model. However, the present disclosure is not limited thereto. For example, an information processing apparatus that controls the substrate processing system 3 and an information processing apparatus that performs optimization using a system model may be separately provided. In this case, for example, a processing result of optimization performed by one information processing apparatus may be supplied to another information processing apparatus, and the control of the substrate processing system 3 may be performed by another information processing apparatus using the result. Further, the processing performed by the information processing system according to the present embodiment may be appropriately distributed and performed by three or more information processing apparatuses.

The setting reception unit 11b receives, from the user, settings for performing optimization processing using the system model of the substrate processing system 3, for example, settings of an objective function, constraints, or the like. For example, the setting reception unit 11b displays a graph of the hierarchical structure (tree structure) of the system model illustrated in FIG. 1 on the display 14, and receives an operation of connecting the objective function G to any component model in the first hierarchy of the system model, an operation of inputting a specific function of the objective function G, and the like, thereby receiving the objective function G for optimization from the user. Further, the setting reception unit 11b can receive constraints for each component model from the user by receiving, for example, an operation of selecting a component model from the displayed graph of the hierarchical structure of the system model, and an operation of inputting specific constraints for the selected component model. The method of receiving the input of these objective functions and constraints is merely an example, and is not limited thereto. The setting reception unit 11b may receive the setting by any method.

The optimization processor 11c performs processing of determining operation conditions of the substrate processing system 3 that optimize the objectives represented by the objective function, based on the system model of the substrate processing system 3 stored in the model information storage 12b and the settings such as the objective function and the constraints received by the setting reception unit 11b from the user. In the present embodiment, the system model to which the objective function is coupled has a tree structure in which the objective function is the root node. The optimization processor 11c recursively traces the hierarchy from the upper level to the lower level, that is, in the order from the objective function that is the root node to the component model in the first hierarchy, the component model in the second hierarchy, . . . , and determines the range (allowed region) for the input data of each component model that can be taken for the optimization of the objective function. The optimization processor 11c can finally determine the allowed region for input data to the system model by tracing the hierarchical structure of the system model from the upper level to the lower level and determining the allowed region for input data. The determined allowed region for input data to the system model is input data to the substrate processing system 3, which optimizes an objective function. The substrate processing system 3 can be optimally operated by operating within this allowed region.

The display processor 11d performs processing of displaying various characters and images on the display 14. In the present embodiment, the display processor 11d displays, on the display 14, various types of data obtained from the substrate processing system 3 operating under the control of the control processor 11a, for example. The display processor 11d also performs the display of a screen for receiving settings by the setting reception unit 11b. Further, the display processor 11d displays information on the optimization results performed by the optimization processor 11c.

### <Optimization Processing>

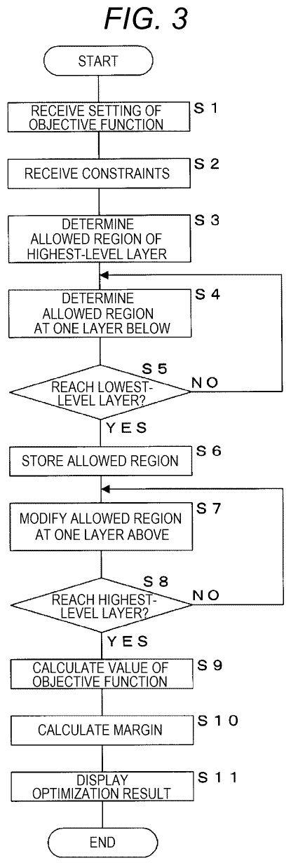

FIG. 3 is a flowchart illustrating an example of a procedure of optimization processing performed by the information processing apparatus 1 according to the present embodiment. The setting reception unit 11b of the processor 11 in the information processing apparatus 1 according to the present embodiment receives an input of a setting of an objective function related to the optimization of the substrate processing system 3, based on an operation of the operator 15 by the user (step S1). The setting reception unit 11b receives settings of constraints related to component models included in the system model of the substrate processing system 3 (step S2). At this time, for example, the processor 11 may display an input screen including a graph or the like illustrating the configuration of the system model of the substrate processing system 3 on the display 14, and receive the input of the objective function and the constraints performed by the user.

The optimization processor 11c of the processor 11 couples the objective function whose setting is received in step S1 to the system model to form a tree structure, and determines a range (an allowed region) of an input for optimizing (maximizing or minimizing) the output of the objective function that is the highest-level layer (root node) thereof (step S3).

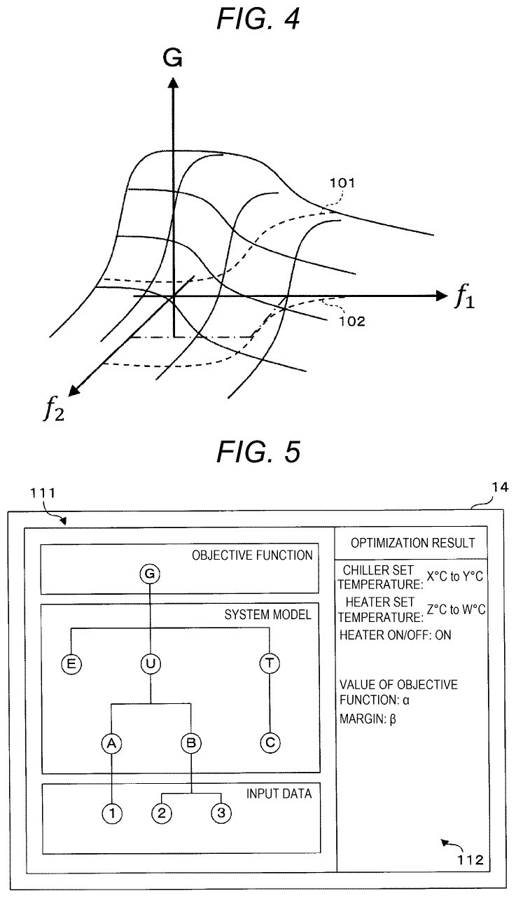

FIG. 4 is a schematic diagram illustrating an example of a method for determining an allowed region. In the present example, it is assumed that the two component models in the first hierarchy of the system model are coupled to the highest-level objective function. The graph illustrated in FIG. 4 is a three-dimensional graph illustrating a correspondence relationship among f1, f2, and G, where f1 is an output value of a first component model in the first hierarchy, f2 is an output value of a second component model, and G is an output value of the objective function corresponding to these two values f1 and f2. In the present example, the output value G of the objective function is set to exceed a predetermined threshold value for the objective of optimization, and the constraints f1≥0 and f2≥0 are set. In this case, in the illustrated graph, a boundary line 101 indicated by a broken line corresponds to the threshold value, and a region above the boundary line 101 becomes an area that satisfies the objective. The boundary line 101 projected onto an f1-f2 plane is a boundary line 102 indicated by a broken line in the illustrated graph. The region surrounded by the boundary line 102, a f1 axis, and a f2 axis is a region where the objective function can be optimized. In other words, this region will be referred to as an allowable region separately from the allowed region. When a combination of f1 and f2 included in the allowable region is obtained, the output value G of the objective function exceeds the threshold value.

Further, the information processing apparatus 1 according to the present embodiment determines one rectangular region (super-rectangular parallelepiped region) included in the allowable region obtained by the method described above. In the illustrated graph, an example of a rectangular region is shown by a dot-chain line. A plurality of rectangular regions may be included in one allowable region, and the information processing apparatus 1 selects, for example, a rectangular region having the largest area from the plurality of rectangular regions. However, the information processing apparatus 1 may select, for example, a rectangular region closest to the square, or may select, for example, one rectangular region at random. The information processing apparatus 1 may determine one rectangular region through a predetermined procedure. The information processing apparatus 1 uses one rectangular region determined from a non-rectangular allowable region as an allowed region as the processing result of step S3 in the flowchart illustrated in FIG. 3, and performs subsequent steps.

In the rectangular allowed region determined in this way, f1 and f2 that are inputs to the objective function can vary independently. The range of f1 falling within this rectangular region can be used as an objective of an optimization for a component model outputting this f1. Similarly, the range of f2 falling within this rectangular region can be used as an objective of an optimization for a component model outputting this f2. Since f1 and f2 can be independently changed, the optimization for the component model outputting f1 and the optimization for the component model outputting f2 can be separately performed. The information processing apparatus 1 can determine an allowable range of inputs for the component model outputting f1 in the same method, and can determine an allowable range of inputs for the component model outputting f2 in the same method. The information processing apparatus 1 can ultimately determine an allowed region related to the input to the system model by recursively repeating the processing of determining a rectangular allowed region in order from an upper hierarchy to a lower hierarchy.

When the rectangular region is determined as the allowed region in order from the upper hierarchy to the lower hierarchy, a situation may occur in which an allowable region or a rectangular region cannot be obtained in the lower hierarchy in the rectangular region determined in the upper hierarchy. In this case, the information processing apparatus 1 may reselect the rectangular region by backtracking one or more hierarchies. For example, when an allowable region or a rectangular region is not obtained, the information processing apparatus 1 first repeats reselection of another rectangular region by backtracking by one hierarchy to an upper hierarchy, and reselects a rectangular region by further backtracking to an upper hierarchy when the allowable region or the rectangular region is not obtained even if a predetermined number of reselections are performed. The information processing apparatus 1 may reselect a rectangular region by any reference, and may feed back information that may contribute to the reselection from the lower hierarchy to the upper hierarchy.

Further, the information processing apparatus 1 may select two or more rectangular regions from the allowable regions, and may set a plurality of rectangular regions as the allowed regions. In this case, the information processing apparatus 1 preferably selects a plurality of rectangular regions so as not to have any overlap therebetween. However, a part of the plurality of rectangular regions may have some overlap. When a plurality of allowed regions are determined in the upper hierarchy, the information processing apparatus 1 can determine an allowable region for each allowed region in the lower hierarchy, select a rectangular region from each allowable region, and discard the remaining rectangular regions by selecting, for example, one rectangular region having a large area from the plurality of selected rectangular regions, according to a predetermined condition. Further, the information processing apparatus 1 may repeat the selection of the rectangular region to the lowest-level layer while maintaining the plurality of allowed regions in parallel without discarding the rectangular region in the lower hierarchy. When the information processing apparatus 1 is enabled to determine a plurality of rectangular regions as allowed regions, for example, a significant limitation can be prevented from being imposed on the selection of the rectangular region in the lower hierarchy, which is caused by insufficiently large rectangular regions due to a complex shape of the allowable region.

In the present example, the case where the inputs to the objective function are two inputs has been described by way of example. Alternatively, the allowed regions may also be determined in the same manner when the inputs are one or three or more. For example, in the case of one input, the above-described rectangular region becomes, for example, a region in a shape of a straight line (line segment). For example, in the case of three inputs, the above-described rectangular region becomes, for example, a rectangular parallelepiped region. That is, the expression “rectangular region” used in the above-described description is an expression limited to two dimensions, and may be referred to as, for example, a “super-rectangular parallelepiped region” when extended in multiple dimensions. The super-rectangular parallelepiped region is a line segment in one dimension, a rectangle (rectangle) in two dimensions, and a cuboid region in three dimensions. Four or more dimensions are also defined in the same manner.

The optimization processor 11c that has determined the allowed region for the input data of the objective function in step S3 of FIG. 3 determines an allowed region for the input data in the same manner for one or more component models located at one layer below (step S4). The optimization processor 11c determines whether the processing of determining the allowed region for input data for the multiple-hierarchy component models constituting the system model has reached the lowest-level layer (step S5). If the processing does not reach the lowest-level layer (S5: NO), the optimization processor 11c returns the processing to step S4, and performs processing of determining an allowed region for input data for the component model at one layer below. The optimization processor 11c recursively repeats the processing of determining the allowed region in order from the upper hierarchy to the lower hierarchy, and if it is determined that the processing has reached the lowest-level layer (S5: YES), the optimization processor 11c stores information on the allowed region determined for the input data of the lowest-level layer in the storage 12 as the optimization result (step S6).

Next, the optimization processor 11c performs processing of modifying, based on the allowed region determined for the input data of the lowest-level layer, the allowed region determined in step S4 for the component model at one layer above (step S7). At this time, when data within the allowed region determined for the lowest-level layer is input into a component model, the optimization processor 11c calculates a range of data output by this component model, and modifies the allowed region related to the input of the component model at one layer above, so as to be within the calculated range. The optimization processor 11c recursively repeats processing of modifying the allowed region in the same manner from a component model in the lowest-level layer to an objective function in the highest-level layer, and finally modifies the allowed region for the input data of the objective function. Accordingly, when the allowed region of the lower hierarchy is limited by, for example, hardware constraints, the optimization processor 11c can feed back this content to the upper hierarchy, and modify the allowed region of the upper hierarchy in a feasible range.

The optimization processor 11c determines whether the processing of modifying the allowed region for the component model at one layer above has reached the highest level layer (step S8). If the processing does not reach the highest-level layer (S8: NO), the optimization processor 11c returns the processing to step S7, and performs processing of modifying the allowed region for the component model at one layer above. The optimization processor 11c repeats the processing of modifying the allowed region in order from the lower hierarchy to the upper hierarchy, and if it is determined that the processing has reached to the highest-level layer (S8: YES), the optimization processor 11c calculates an output value (or a range of output values) of the objective function corresponding to the modified allowed region for the objective function that is the highest-level layer (step S9).

Next, the optimization processor 11c calculates a margin indicating how much margin there is for the set optimization objective with respect to the value of the objective function calculated in step S9 or the range thereof (step S10). For example, when the output of the objective function needs to exceed the set threshold value, the difference or ratio between the output value of the objective function calculated in step S9 and the set threshold value may be used as the margin. The display processor 11d of the processor 11 displays the optimization result including the information such as the allowed region stored in step S6, the value of the objective function calculated in step S9, and the margin calculated in step S10 on the display 14 (step S11), and ends the processing.

For example, when the margin calculated in step S10 exceeds a predetermined margin, i.e., when there is a sufficient margin, the information processing apparatus 1 may adjust the threshold value for the output of the objective function in a direction in which the threshold value becomes stricter (i.e., increase the threshold value if maximization is performed, decrease the threshold value if minimization is performed), and repeat the processing in steps S3 to S10. When the optimization processing is repeated by adjusting the threshold value until the margin becomes zero (0) or close to zero (0), the information processing apparatus 1 can obtain a more suitable (optimal) output value of an objective function and an input value of a system model that implements the output value.

FIG. 5 is a schematic diagram illustrating a display example of an optimization result. The information processing apparatus 1 according to the present embodiment displays an optimization result display screen illustrated in FIG. 5 on the display 14 in step S11, based on the information obtained through the optimization processing in steps S1 to S10 of the flowchart illustrated in FIG. 3. The optimization result display screen of the present example includes, for example, a model structure display area 111 that displays a hierarchical structure of the system model that is an optimization target, and an optimization result display area 112 that displays various types of information obtained through the optimization processing, which are arranged side by side. The model structure display area III displays a graph in which a plurality of component models and associated objective functions and input data included in the system model of the substrate processing system 3 that is the optimization target are defined as nodes, and the plurality of nodes are connected by lines.

In the optimization result display area 112, for example, a title character string of “optimization result” is displayed at an uppermost portion, and various types of information are listed below this title character string. In the illustrated example, it is shown that it is optimal to set, for example, the chiller set temperature to X° C. to Y° C., the heater set temperature to Z° C. to W° C., and ON as the heater ON/OFF setting as the input data to the system model. Further, it is shown that the predicted value of the value of the objective function when substrate processing by the substrate processing system 3 is performed within these setting ranges is a, and the margin for the target set in advance is p.

Further, when the optimization result display screen is being displayed on the display 14, the information processing apparatus 1 receives an operation of selecting, for example, an objective function displayed on the model structure display area 111. The information processing apparatus 1 displays an objective function setting screen or the like on the display 14 in response to the operation of selecting the objective function, and receives the operation of resetting the objective function by the user. The information processing apparatus 1, which has received the resetting of the objective function, can perform optimization processing based on the reset objective function through the same procedure, and update the information on the optimization result displayed on the optimization result display screen.

The configuration of the optimization result display screen illustrated in FIG. 5 is an example, and is not limited thereto. The information processing apparatus 1 may display the information obtained through the optimization in any form and provide the information to the user.

### Modification Examples

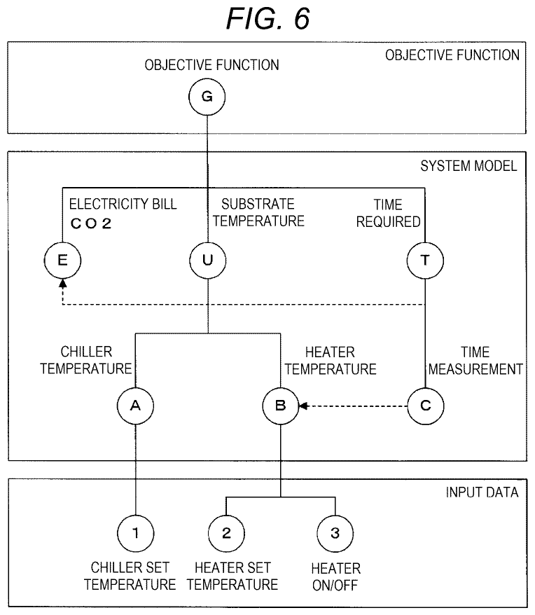

FIG. 6 is a schematic diagram illustrating an example of a configuration of a system model according to a modification. The system model shown in FIG. 1 described above has a configuration in which an objective function is set as a root node, and a plurality of component models are connected as nodes to form a tree structure with respect to the root node. In the system model having a tree structure, an output of a certain node is input to one node in the next higher hierarchy. However, in a case of modeling the substrate processing system 3, it may be difficult to model the substrate processing system 3 with such a complete tree structure.

Therefore, the system model according to the modification is based on a configuration in which a root node (objective function) and a plurality of nodes (component models) are connected in a tree structure, and a configuration in which, for example, output data of one node is input to a plurality of nodes in an upper hierarchy, and a configuration in which output data of one node is input to other nodes of the same hierarchy are allowed in some of the system models. In the system model of the modification illustrated in FIG. 6, for example, the output data of the component model C is input to the component model T in the upper hierarchy, and is also input to the component model E in the upper hierarchy and the component model B in the same hierarchy.

The information processing apparatus 1 according to the modification determines an allowed region (rectangular region) related to the output data of the component model C, based on, for example, a rectangular region determined based on the component model T, a rectangular region determined based on the component model E, and a rectangular region determined based on the component model B. For example, the information processing apparatus 1 may set a region where the three rectangular regions overlap with each other as a rectangular region related to the output data of the component model C.

### SUMMARY

In the information processing system according to the present embodiment having the configuration described above, the information processing apparatus 1 stores, in the model information storage 12b, a system model in which a plurality of component models, each of which is obtained by modeling a plurality of physical components included in the physical system such as the substrate processing system 3, are coupled in a hierarchical manner. The information processing apparatus 1 determines an allowed region for input data such that the output value of the objective function satisfies a predetermined condition. Regarding the component model for outputting the input data, the information processing apparatus 1 determines the allowed region for the input data of the component model such that the output value of the component model falls within the determined allowed region. The information processing apparatus 1 recursively repeats the determination of the allowed region for input data in the order from the upper hierarchy to the lower hierarchy (from an output side to an input side of the hierarchy) for the plurality of component models constituting the system model, and finally determines the allowed region for input data of the system model. Accordingly, the information processing system according to the present embodiment can determine the allowed region for input data of the system model in which the objective function can be optimized, and can be expected to optimize the operation of the substrate processing system 3 by operating the substrate processing system 3 with the input data within the determined allowed region.

In the information processing system according to the present embodiment, the information processing apparatus 1 determines the rectangular region included in the determined allowable region. The information processing apparatus 1 recursively repeats the determination of the rectangular region in the order from the upper hierarchy to the lower hierarchy for the plurality of component models constituting the system model. Accordingly, the information processing system can handle the allowed regions determined for each of the plurality of pieces of input data to the component model independently, and can be expected to facilitate the determination of the allowed regions recursively performed from the upper hierarchy to the lower hierarchy.

In the information processing system according to the present embodiment, after determining the allowed region for input data of the system model, the information processing apparatus 1 recursively and repeatedly modifies the allowed region from the lower hierarchy to the upper hierarchy (from the input side to the output side) to finally calculate the output value of the objective function. Accordingly, the information processing system can predict the output value of the objective function when the substrate processing system 3 is operated using input data within the allowed region, and calculate, for example, the margin for a set objective.

In the information processing system according to the present embodiment, the information processing apparatus 1 displays information on the determined allowed region for input data of the system model and the calculated output value of the objective function on the display 14 as the optimization result. At this time, the information processing apparatus 1 may display, for example, a graph showing the configuration of a system model in which a component model is set as a node and a plurality of nodes are connected by lines. The user can review the validity of the objective function set by the user himself/herself, for example, and reset the objective function based on the display of these pieces of information.

In the information processing system according to the present embodiment, the system model obtained by modeling the substrate processing system 3 is a tree-structure model in which a plurality of component models are hierarchically coupled with an objective function as a root node. The model having such a tree structure is suitable for the optimization processing of recursively repeating the determination of the allowed region from the upper hierarchy to the lower hierarchy performed by the information processing apparatus 1.

In the present embodiment, the substrate processing system 3 has been described by taking, as an example, the physical system handled by the information processing system. However, the physical system is not limited to the substrate processing system 3, and may be various systems in which physical components can be modeled. The structure of the system model illustrated in FIG. 1 is an example, and is not limited thereto.

### Second Embodiment

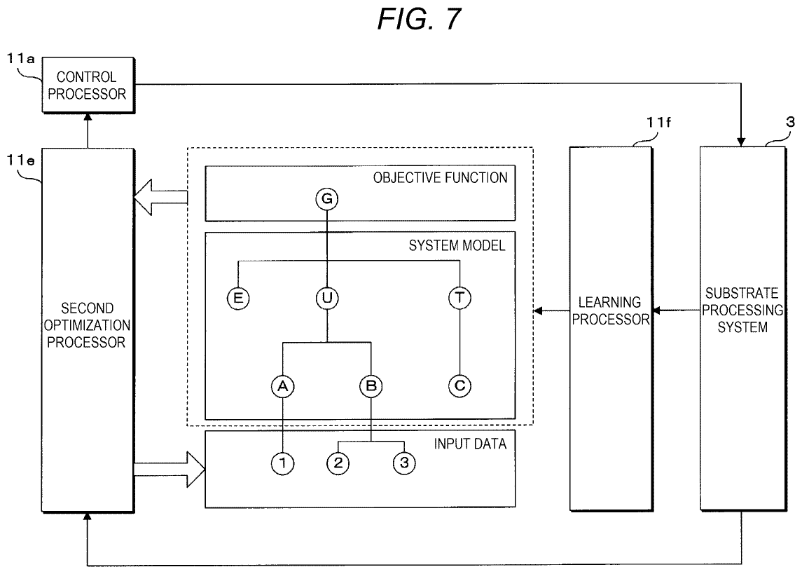

FIG. 7 is a schematic diagram illustrating an example of an overview of an information processing system according to the second embodiment. The information processing system according to the second embodiment optimizes the system model, the objective function, and the like provided in the information processing system described in the first embodiment by using a method such as training or data assimilation.

In the second embodiment, the system model and the objective function (a block surrounded by the broken line in FIG. 7) will be referred to as a digital twin. The digital twin includes a hardware model that mimics the operation of the unit of a target apparatus, an interaction model that reflects a physical correlation of a plurality of units, and a control model that controls the unit.

When the physical system handled by the system model is the substrate processing system 3, the substrate processing system 3 needs to be operated under a plurality of operation conditions (recipes). Therefore, parameters that differ depending on the operation conditions, among internal parameters of the digital twin and the parameters used for optimization processing, are held in the information processing apparatus 1. The information processing apparatus 1 can switch these parameters according to the operation conditions of the substrate processing system 3 to use the digital twin. The internal parameters of the digital twin may include, for example, states of the various apparatuses provided in the system model, and the internal parameters of a prediction model for performing prediction based on the apparatus states and input signals.

The information processing apparatus 1 according to the second embodiment includes a second optimization processor 11e, a learning processor 11f, and the like, in addition to the configuration of the information processing apparatus 1 according to the first embodiment. The second optimization processor 11e and the learning processor 11f are software functional units implemented by executing the program 12a in the storage 12 by the processor 11.

The second optimization processor 11e operates the substrate processing system 3 via the control processor 11a based on the optimal operation conditions of the digital twin (the substrate processing system 3) obtained through the optimization processing by the optimization processor 11c. The second optimization processor 11e compares a sensor value obtained as an operation result of the substrate processing system 3 with the predicted value of the sensor value obtained by using the digital twin.

When it is determined that an error between the actual operation result by the substrate processing system 3 and the prediction result of the digital twin is large, the second optimization processor 11e performs training (optimization) of the digital twin or data assimilation, and updates the internal parameters of the digital twin to optimize the digital twin. The internal parameters of the digital twin may include those that are prohibited from being updated at this time point.

When the operation of the substrate processing system 3 is performed by the second optimization processor 11e, the learning processor 11f acquires input data (e.g., operation conditions) to the substrate processing system 3 and output data (e.g., sensor values), and stores the acquired input and output data as learning data in an associated manner. When the second optimization processor 11e determines to perform optimization of the digital twin, the learning processor 11f updates the internal parameters of the digital twin by performing learning (optimization) using the stored learning data. For the update of the internal parameters of the digital twin, for example, an algorithm such as deep layer expansion, a differentiable algorithm, a gradient method, a grid search, a random search, an evolutionary calculation (genetic algorithm or group intelligence), a Bayesian optimization, a quantum annealing, or a combinatorial optimization or a continuous value optimization using a gate-type quantum computer may be adopted.

In the present embodiment, the learning processor 11f performs training of the digital twin to improve prediction accuracy. However, the present disclosure is not limited thereto, and for example, the prediction accuracy of the digital twin may be improved by performing data assimilation processing. The data assimilation is a method of predicting and updating the internal state of a digital twin using both observation data including errors of sensor values or the like and prediction data of the digital twin, such as a Kalman filter or a particle filter.

Further, the information processing apparatus 1 may update parameters of an optimization algorithm for determination by optimizing the allowed region for input data according to the same method as the update of the internal parameters of the digital twin. The parameters of the optimization algorithm are values that can be set by the user such as a learning rate or the number of repetitions when, for example, a steepest descent method is adopted as the optimization algorithm for determining the allowed region for input data, and are so-called hyperparameters. The information processing apparatus 1 can gradually reduce the time required for the optimization by, for example, carefully optimizing (modifying the allowed region) by setting the learning rate to be small and the maximum number of repetitions to be large at an initial stage of the optimization for determining the allowed region for input data, and gradually updating (optimizing) the learning rate and the maximum number of repetitions. The optimization algorithm is not limited to the steepest descent method, and various algorithms such as the quasi-Newton method or the Newton method may be adopted. For example, the optimization algorithm may include a neural network or the like, and in these cases, it is expected that the time required for the optimization processing may also be shortened by updating the adjustable parameters by the information processing apparatus 1.

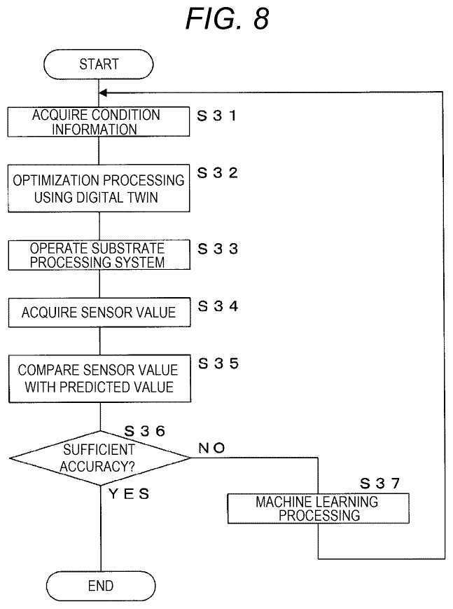

FIG. 8 is a flowchart illustrating an example of a procedure of optimization processing performed by the information processing apparatus 1 according to the second embodiment. The second optimization processor 11e of the processor 11 in the information processing apparatus 1 according to the second embodiment acquires condition information for optimization such as operation conditions, apparatus states, and constraints related to the target substrate processing system 3 (step S1).

Next, the optimization processor 11c of the processor 11 performs optimization processing using the digital twin (step S32). The processing performed by the optimization processor 11c in this step is optimization processing illustrated in FIG. 3, and is processing for predicting optimal values for the range of inputs and the values of outputs of the substrate processing system 3 using the digital twin.

The second optimization processor 11e of the processor 11 performs an operation of the substrate processing system 3 based on the optimal input range obtained through the optimization processing in step S32 (step S33). At this time, the second optimization processor 11e determines the operation conditions and the like of the substrate processing system 3 based on the optimal input range, and gives an instruction to perform an operation based on the determined operation conditions and the like to the control processor 11a, so as to operate the substrate processing system 3.

The second optimization processor 11e acquires a sensor value measured by a sensor provided in the substrate processing system 3, as the operation result of the substrate processing system 3 (step S34). The second optimization processor 11e compares the sensor value obtained in step S34 with the predicted value of the sensor value obtained as the output of the digital twin during the optimization processing in step S32 (step S35). For example, when the value predicted using the digital twin is a value that cannot be directly measured by the sensor in the substrate processing system 3, the second optimization processor 11e may perform an appropriate arithmetic operation on the obtained sensor value, convert the sensor value into information of the same type as the predicted value, and perform a comparison. Similarly, the second optimization processor 11e may perform an appropriate arithmetic operation on the predicted value obtained by the digital twin, convert the predicted value into information of the same type as the sensor value, and perform a comparison.

Based on the comparison result in step S35, the second optimization processor 11e determines whether prediction using the digital twin is sufficiently accurate by determining, for example, whether the error between the sensor value and the predicted value is less than a threshold value (step S36).

If the prediction using the digital twin is not sufficiently accurate (S36: NO), the learning processor 11f of the processor 11 performs the learning processing based on the data obtained along with the operation of the substrate processing system 3 in step S33 (step S37), and returns the processing to step S31. If the prediction using the digital twin is sufficiently accurate (S36: YES), the second optimization processor 11e ends the processing.

The information processing apparatus 1 can predict the presence or absence of a failure in the substrate processing system 3 based on the comparison result between the sensor value measured by the sensor in the substrate processing system 3 and the predicted value of the sensor value obtained as the output of the digital twin through the optimization processing.

Further, when data necessary for the learning processing is insufficient, the information processing apparatus 1 may determine experimental conditions necessary for compensating for the insufficient data, and may display the determined experimental conditions and propose the determined experimental conditions to the user.

The determination as to whether data necessary for the learning processing is sufficient or insufficient can be performed through, for example, an existing Bayesian optimization method. For example, when the Bayesian optimization processing is performed including a distribution of the parameters of the model adjusted through the learning processing, and the width of the distribution becomes smaller, it can be considered that the information increases due to the new data and the uncertainty of the model is reduced, and it can be determined that the data necessary for the learning processing is sufficient. The information processing apparatus 1 can determine that the data is sufficient when the statistics (variance, standard deviation, interquartile intervals, or the like) regarding the distribution satisfy a predetermined criterion, and can determine that the data is insufficient when the statistics do not satisfy the criterion.

The determination of the experimental conditions necessary to compensate for the insufficient data can also be performed through a Bayesian optimization method. The information processing apparatus 1 can determine such experimental conditions as to reduce the uncertainty of the model by a Bayesian optimization method. When the Bayesian optimization is not used, for example, the information processing apparatus 1 can perform prediction using an existing model based on certain experimental conditions, add data assuming that the prediction results are actual measured values, perform learning processing using the data to calculate uncertainty of the model, and determine the experimental conditions such that the amount of reduction of the uncertainty becomes maximum.

Further, the determination as to whether the data necessary for the learning processing is sufficient or insufficient, and the determination of the experimental conditions necessary for compensating the insufficient data may be performed by the user, instead of the information processing apparatus 1. The information processing apparatus 1 can display information such as a value indicating uncertainty of a model, inquire of the user as to whether data necessary for the learning processing is sufficient or insufficient, and receive the determination by the user. Further, when the user determines that the data is insufficient, the information processing apparatus 1 can receive the input of experimental conditions for compensating the insufficient data from the user, perform the substrate processing by the substrate processing system 3 under the received experimental conditions, and collect necessary data.

In the information processing system according to the second embodiment having the above configuration, the information processing apparatus 1 operates the physical substrate processing system 3 based on the allowed region for the input to the digital twin determined by the optimization according to the first embodiment. The information processing apparatus 1 acquires the sensor value and the like as the operation result of the substrate processing system 3, and performs optimization such as training of the digital twin or data assimilation based on the acquired sensor values. Accordingly, the information processing system according to the second embodiment can be expected to optimize the digital twin to improve prediction accuracy and the like. A part or all of the digital twin for which sufficient accuracy has been obtained through the optimization may be applied to a system different from the information processing system according to the present embodiment. For example, the use of digital twins can be expected in the prediction of failure of a physical system, the development of hardware based on a model, or the design of recipes for the substrate processing system 3.

Since the other configurations of the information processing system according to the second embodiment are the same as those of the information processing system according to the first embodiment, the same reference numerals are given to the same locations, and a detailed description thereof will be omitted.

The embodiments disclosed herein are exemplary in all respects and can be considered to be not restrictive. The scope of the present disclosure is indicated by the claims, not the above-described meaning, and is intended to include all modifications within the meaning and scope equivalent to the claims.

The features described in each embodiment can be combined with each other. In addition, the independent and dependent claims set forth in the claims can be combined with each other in any and all combinations, regardless of the reciting format.

1. An information processing method comprising, by an information processing apparatus:
storing, in a memory circuit, a system model obtained by coupling component models obtained by respectively modeling physical components included in a physical system and modeling the physical system,
receiving a setting of an objective function for performing an arithmetic operation based on an output value of the system model,
determining an allowed region for an input value for the system model, in which an output value of the objective function satisfies a predetermined condition,
determining an allowed region for an input value of the component model in which an output value of the component model falls within the allowed region, for the component model outputting the input value, and
determining an allowed region for the input value of the system model by determining the allowed region for component models constituting the system model.

2. The information processing method according to claim 1, wherein
the system model is a model in which the component models are coupled in a hierarchical manner, and
to determine the allowed region for the input value of the system model, the method further comprises recursively determining the allowed region for the input value from an output side to an input side of a hierarchy for the component models constituting the system model.

3. The information processing method according to claim 2, further comprising:
determining an allowable region for the input value, in which the output value satisfies the allowed region;
determining a super-rectangular parallelepiped region included in the determined allowable region; and
defining the determined super-rectangular parallelepiped region as the allowed region for the input value.

4. The information processing method according to claim 2, further comprising:
modifying an allowed region related to the output value of the component model receiving the input value based on the determined allowed region for the input value of the system model;
modifying an allowed region related to the output value of the component model receiving the output value based on the modified allowed region for the output value;
recursively modifying the allowed region related to the output value in order from the input side to the output side of the hierarchy for the component models constituting the system model; and
calculating the output value of the objective function based on the modified allowed region.

5. The information processing method according to claim 4, further comprising:
displaying information on the determined allowed region for the input value of the system model and the calculated output value of the objective function on a display; and
receiving a resetting of the objective function.

6. The information processing method according to claim 5, further comprising:
generating a graph of the system model in which the component model is defined as a node, and nodes are connected by lines; and
displaying the generated graph on the display together with the information.

7. The information processing method according to claim 1, wherein
the system model is a model having a tree structure in which the component models are coupled in a hierarchical manner using the objective function as a root node.

8. The information processing method according to claim 1, further comprising:
controlling operation of the physical system based on the determined allowed region;
acquiring an operation result of the physical system; and
optimizing a parameter of the system model or a parameter of an algorithm for determining the allowed region for the input value of the system model based on the acquired operation result; and
controlling operation of the physical system based on an optimized one of the parameter of the system mode optimized or the parameter of the algorithm for determining the allowed region for the input value of the system model.

9. The information processing method according to claim 8, further comprising:
optimizing the parameter of the system model or the parameter of the algorithm for determining the allowed region for the input value of the system model based on a comparison between the operation result of the physical system and a prediction result obtained by the system model.

10. The information processing method according to claim 8, further comprising:
performing the optimization of the parameter of the system model or the parameter of the algorithm for determining the allowed region for the input value of the system model by data assimilation.

11. The information processing method according to claim 8, further comprising:
estimating, during the optimization of the parameter and when data related to the operation result of the physical system is insufficient, an operation condition of the physical system for acquiring the insufficient data; and
outputting the estimated operation condition.

12. The information processing method according to claim 1, further comprising:
storing a plurality of the system models or parameters of the system model in the memory circuit; and
selecting the system models or the parameters of the system models according to an operation condition of the physical system.

13. The information processing method according to claim 1, further comprising controlling the physical system based on the determined allowed region for an input value of the system model.

14. The information processing method according to claim 13, further comprising predicting at least one of quality and accuracy of processing performed by the physical system based on the system model, and adjusting control of the physical system based on the predicted at least one of the quality and the accuracy.

15. A non-transitory computer-readable medium storing a computer program that, when executed by a computer, causes the computer to perform a method comprising:
storing, in a memory circuit, a system model obtained by coupling component models obtained by respectively modeling physical components included in a physical system and modeling the physical system,
receiving a setting of an objective function for performing an arithmetic operation based on an output value of the system model,
determining an allowed region for an input value for the system model, in which an output value of the objective function satisfies a predetermined condition,
determining an allowed region for an input value of the component model in which an output value of the component model falls within the allowed region, for the component model outputting the input value, and
determining an allowed region for the input value of the system model by determining the allowed region for the component models constituting the system model.

16. The non-transitory computer-readable medium according to claim 15, further comprising controlling the physical system based on the determined allowed region for an input value of the system model.

17. The non-transitory computer-readable medium according to claim 16, further comprising predicting at least one of quality and accuracy of processing performed by the physical system based on the system model, and adjusting control of the physical system based on the predicted at least one of the quality and the accuracy.

18. An information processing apparatus, comprising:
a processor circuitry, and
a memory circuit in which a system model obtained by coupling component models obtained by respectively modeling physical components included in a physical system and modeling the physical system is stored, wherein
the circuitry
receives a setting of an objective function for performing an arithmetic operation based on an output value of the system model,
determines an allowed region for an input value for the system model, in which an output value of the objective function satisfies a predetermined condition,
determines an allowed region for an input value of the component model in which an output value of the component model falls within the allowed region, for the component model outputting the input value, and
determines an allowed region for the input value of the system model by determining the allowed region for the component models constituting the system model.

19. The information processing apparatus according to claim 18, wherein the circuitry further controls the physical system based on the determined allowed region for an input value of the system model.

20. The information processing method according to claim 19, wherein the circuitry further predicts at least one of quality and accuracy of processing performed by the physical system based on the system model, and adjusts control of the physical system based on the predicted at least one of the quality and the accuracy.
